(19) United States
(12) Patent Application Publication
(10) Pub. No.: US 2026/0223422 A1
(43) Pub. Date: Jul. 30, 2026

(54) Semiconductor Device and Method of Forming High Power, High Frequency Semiconductor Structure on Diamond Substrate

(71) Applicant: Advent Diamond, Inc., Scottsdale, AZ (US)

(72) Inventors: Jose Andres Orozco, Chandler, AZ (US); Manpuneet Kaur Benipal, Gilbert, AZ (US); Anna Zaniewski, Pittsburgh, PA (US); Jesse Brown, Gilbert, AZ (US)

(73) Assignee: Advent Diamond, Inc., Scottsdale, AZ (US)

(21) Appl. No.: 19/038,745

(22) Filed: Jan. 28, 2025

(51) Int. Cl. H10D 62/83; H10D 8/01; H10D 8/50

(52) U.S. Cl. CPC H10D 62/8303; H10D 8/01; H10D 8/50

(57) ABSTRACT

A semiconductor device has a substrate with a diamond material and a first diamond layer formed over a surface of the substrate. An insulating layer is formed over the first diamond layer. The insulating layer has a first graded edge and a second graded edge. A second diamond layer is formed over the first diamond layer. The first diamond layer has a dopant material and the second diamond layer has an intrinsic material. A third diamond layer can be formed over the second diamond layer. A first conductive layer is formed over the insulating layer and contacts the first diamond layer, and a second conductive layer is formed over the insulating layer and contacts the second diamond layer. The first conductive layer and second conductive layer can be interdigitated. The semiconductor device can be a vertical or quasi-vertical diode or transistor.

### FIELD OF THE INVENTION

The present invention relates in general to a semiconductor device and, more particularly, to a semiconductor device and method of forming a high power, high frequency semiconductor structure on a diamond substrate.

### BACKGROUND OF THE INVENTION

Semiconductor devices are commonly found in modern electrical products. Semiconductor devices vary in the number and density of electrical components. Discrete semiconductor devices generally contain one type of electrical component, e.g., a light emitting diode (LED), small signal transistor, electrical diode, resistor, capacitor, inductor, and power metal oxide semiconductor field effect transistor (MOSFET). Integrated semiconductor devices typically contain hundreds to millions of electrical components. Examples of integrated semiconductor devices include microcontrollers, microprocessors, interface circuits, and other signal processing circuits.

Semiconductor devices perform a wide range of functions, such as signal processing, high-speed calculations, transmitting and receiving electromagnetic signals, controlling electrical devices, transforming sunlight to electricity, and creating visual projections for television displays. Semiconductor devices are found in the fields of communications, power conversion, networks, computers, and consumer products. Semiconductor devices are also found in military applications, aerospace, aviation, automotive, data processing centers, industrial controllers, and office equipment.

Diamond material has been used as a substrate for semiconductor devices and provides a number of advantages, such as hardness, thermal conductivity, electron mobility, wide bandgap, radiation hardness, and thermal and chemical stability. A diamond epitaxial layer can be grown over a diamond substrate and semiconductor regions can be formed in the epitaxial layer.

Power devices capable of handling large power densities at high and low frequency are integral to power electronics systems. Limitations include current crowding and reduction of the effective device active area, large parasitic capacitance and resistance contributions, thermal management issues leading to poor performance, especially at higher frequencies and/or high power. Most if not all design options require signal extraction away from the active area for any sort of on chip integration between multiple devices. Multiple sharp edges may exist at the intrinsic mesa edge and the boron doped diamond edge. These edges cause a reduction in metal thickness at the edges and contribute to parasitic resistance and inductance. Furthermore, at high power operation, electromigration and burnout becomes probable due to the restriction in the metal thickness. Sharp edges in any dielectric or diamond layer can lead to premature dielectric breakdown.

### BRIEF DESCRIPTION OF THE DRAWINGS

FIGS. 1a-1c illustrate a semiconductor wafer with a plurality of semiconductor die;

FIGS. 2a-2i illustrate a process of forming a first diamond layer over a diamond substrate and a second diamond layer over the first diamond layer to operate as a diode;

FIGS. 3a-3c illustrate formation of graded edges in an insulating layer formed over the first diamond layer;

FIGS. 4a-4c illustrate another embodiment of the diamond diode as a planar and non-planar structure;

FIG. 5 illustrates another embodiment of the diamond diode as a quasi-vertical structure;

FIG. 6 illustrates another embodiment of the diamond diode as PIN structure;

FIG. 7 illustrates another embodiment of the diamond diode as a PIN structure with a doped diamond substrate;

FIG. 8 illustrates another embodiment of the diamond diode with graded active regions;

FIG. 9 illustrates another embodiment of the diamond diode with a vertical structure;

FIG. 10 illustrates another embodiment of the diamond diode with another vertical structure;

FIG. 11 is a graph of Z11 magnitude in ohms versus frequency for the diamond diode; and

FIG. 12 is a graph of current versus voltage for the diamond diode.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The term “semiconductor die” as used herein refers to both the singular and plural form of the words, and accordingly, can refer to both a single semiconductor device and multiple semiconductor devices.

Terms such as first, second, etc., may be used herein to describe various elements, although these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

When an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Terms such as “upper,” “lower,” “bottom,” “intermediate,” “middle,” “top,” and the like may be used herein to describe various elements, although these elements should not be limited by these terms. These terms are only used to distinguish one element from another. For example, a first element could be termed an “upper” element and, similarly, a second element could be termed an “upper” element depending on the relative orientations of these elements, without departing from the scope of the present disclosure. Terms such as “over” and “above” refer to one element being within the vertical projection of another element.

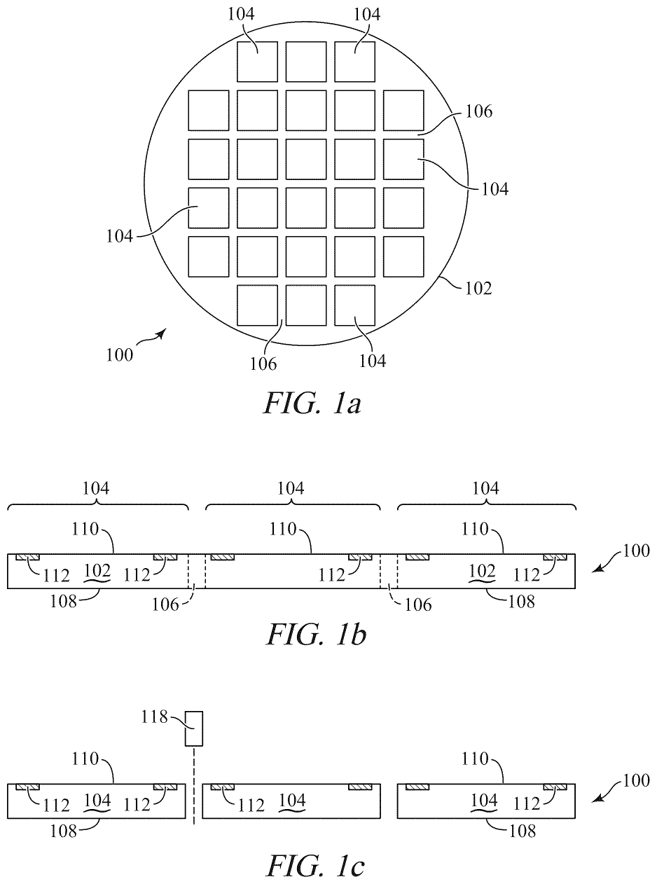

FIG. 1a shows semiconductor wafer or substrate 100 with a base substrate material 102, such as silicon (Si), SiC, cubic silicon carbide (3C-SiC), germanium, aluminum phosphide, aluminum arsenide, gallium arsenide, gallium nitride, indium phosphide, and all families of III-V and II-VI semiconductor materials for structural support. In one embodiment, base substrate material 102 includes a synthesized diamond material. A plurality of semiconductor die or electrical components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 30-100 millimeters (mm) or more.

FIG. 1b shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 110 to implement analog circuits or digital circuits, such as digital signal processor (DSP), application specific integrated circuits (ASIC), memory, discrete semiconductor devices, or other signal processing circuit.

An electrically conductive layer 112 is formed over active surface 110 using PVD, CVD, electrolytic plating, electroless plating process, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits on active surface 110.

In FIG. 1c, semiconductor wafer 100 is singulated through saw street 106 using a saw blade or laser cutting tool 118 into individual semiconductor die 104. The individual semiconductor die 104 can be inspected and electrically tested for identification of known good die or unit (KGD/KGU) post singulation.

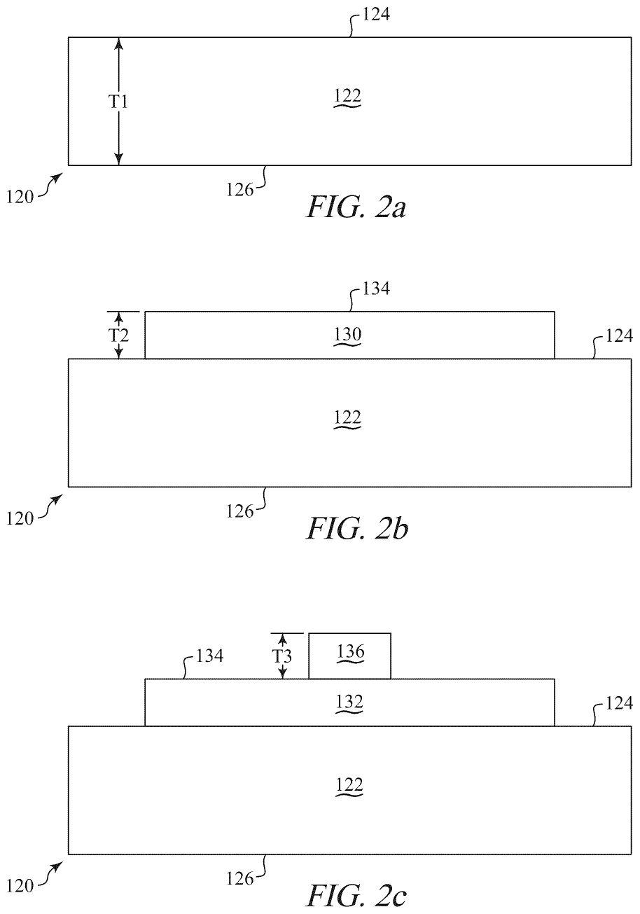

FIG. 2a shows further detail of substrate 120 as the afore-mentioned diamond variant of substrate 100. Substrate 120 has a major surface 124 and major surface 126, opposite major surface 124. Substrate 120 can be a synthesized diamond material 122 formed from crystallized carbon under high temperature and/or high pressure. In particular, diamond material 122 can be synthesized by chemical vapor deposition (CVD), plasma-enhanced chemical vapor deposition (PECVD), or high-pressure, high temperature diamond (HPHT), yet exhibit the same chemical and physical properties as naturally-occurring diamond. For example, CVD creates a carbon plasma or other hydrocarbon gas mixture over a non-diamond substrate onto which the carbon atoms are deposited to form diamond material. In CVD, varying amounts of gases are introduced into a reaction chamber and energized over the non-diamond substrate. The non-diamond substrate is selected for its compatibility to grow diamond and its crystallographic orientation. In one embodiment, the non-diamond substrate can be sapphire, or iridium, or a combination thereof both. The gases are carbon (typically methane) and hydrogen with a typical gas mixture ratio of 1:99. Hydrogen selectively etches off non-diamond carbon. The gases are ionized into chemically active radicals in the growth chamber using microwave, hot filament, arc discharge, welding torch, laser, or electron beam. In another embodiment, hetero diamond is polycrystalline formed by bonding a diamond wafer to different material. CVD provides the ability to grow diamond over large areas and on various substrates, and further provides fine control over the chemical impurities and thus properties of the diamond produced. In its final form, diamond substrate 120 has a thickness T1 in the range of 10.0 μm to 10.0 cm, or preferably in the range of 50.0 μm to 500.0 μm.

Semiconductor substrate 120 with synthesized diamond material 122 exhibits useful properties of hardness (10 Mohs or less), thermal conductivity (10-2000 W/m²K), electron mobility, wide bandgap (5.5 eV), radiation hardness, and thermal and chemical stability. Diamond is an electrical insulator and thermal conductor. Diamond can become an electrical conductor by implanting impurities, such as boron (p-type) or phosphorus (n-type). Such impurities contain one more or one fewer valence electrons than carbon and will turn synthetic diamond into p-type or n-type semiconductor material. As such, substrate 120 is applicable to semiconductor devices, such as power transistors, high power diodes, high frequency transistors and diodes, light emitting diodes (LED), ultra-violet (UV) light detectors, quantum sensing, quantum computing, high-power semiconductor devices, radiation detection, and other high energy semiconductor devices. In the present embodiment, substrate 120 is an intrinsic material.

In FIG. 2b, diamond layer 130 is epitaxially grown on surface 124 of substrate 120. Diamond layer 130 has a thickness T2 in the range of 10.0 nm to 300.0μm. Diamond material 130 is doped with a p-type impurity, such as boron, with a concentration in the range of 1E19-1E21 cm⁻³, or preferably 4E20 cm⁻³, to form a p-type material diamond layer 132, see FIG. 2c. Alternatively, diamond material 132 can be heavily doped with a concentration of 8E20-1E21 cm⁻³. It is understood in all examples herein that doping can be performed with the opposite conductivity material, i.e., p-type material or n-type material. In the present case, the p-type diamond layer 132 allows for formation of electrical semiconductor devices over substrate 120, while utilizing the attributes of diamond, including hardness, thermal conductivity, wide bandgap, and useful mechanical properties. In one embodiment, a high-power, high-frequency interdigitated diode or transistor can be formed on substrate 120 comprising a diamond material.

In FIG. 2c, diamond layer 136 is grown over surface 134 of diamond layer 132 using CVD, PEVCD, or HPHT, as described above. Diamond layer 136 operates as a drift layer. In one embodiment, diamond layer 136 is intrinsic diamond material, i.e., having no impurities. Alternatively, diamond layer 136 is lightly doped with p-type material or n-type material in the range of less than 10¹⁸ cm⁻³. Diamond layer 136 has a thickness T3 in the range of 1.0 nanometers to 100.0 μm.

In FIG. 2d, one or more insulating layers 138 are formed over substrate 120, diamond layer 132, and diamond layer 136 using PVD, CVD, printing, lamination, spin coating, spray coating, sintering or thermal oxidation. Insulating layer 138 can be silicon dioxide (SiO2), silicon nitride (Si3N4), silicon oxynitride (SiON), tantalum pentoxide (Ta2O5), aluminum oxide (Al2O3), solder resist, polyimide, benzocyclobutene (BCB), polybenzoxazoles (PBO), and other material having similar insulating and structural properties. In one embodiment, insulating layer 138 is SiO2, although other low-k dielectrics can be used to further reduce parasitic capacitance and increase device performance. A portion of insulating layer 138 is removed by etching or laser direct ablation (LDA) using layer 140 to expose surface 144 of diamond layer 136.

In FIG. 2e, an electrically conductive layer 142 is formed over insulating layer 138 and surface 144 of diamond layer 136 using PVD, CVD, electrolytic plating, electroless plating process, or other suitable metal deposition process. An electrically conductive layer 146 (shown in subsequent figures) is formed over surface 134 of diamond layer 132 using PVD, CVD, electrolytic plating, electroless plating process, or other suitable metal deposition process. Conductive layers 142 and 146 can be one or more layers of Al, Cu, Sn, Ni, Au, Ag, or other suitable electrically conductive material. In one embodiment, conductive layers 142 and 146 are a carbide material for high temperature contact. The combination of conductive layer 142, doped diamond layer 132, and intrinsic diamond layer 136 operates as an intrinsic Schottky PI diode 150 (p material 132 with intrinsic material 136 and conductive layer 142). In this case, conductive layer 142 is the cathode and conductive layer 146 is the anode of diode 150.

FIG. 2f is a top view of diode 150 showing conductive layers 142 and 146 arranged in an interdigitated pattern over insulating layer 138. Insulating layer 138 is shown between the interdigitated pattern of fingers 154a of conductive layer 142 and fingers 154b of conductive layer 146 as a serpentine pattern. FIG. 2g is a cross-sectional view taken through line segment 2g-2g in FIG. 2f. FIG. 2g shows intrinsic diamond substrate 120, doped diamond layer 132, intrinsic diamond layer 136, insulating layer 138, conductive layer 142, and conductive layer 146. FIG. 2h is a cross-sectional view taken through line segment 2h-2h in FIG. 2f. FIG. 2h shows intrinsic diamond substrate 120, doped diamond layer 132, intrinsic diamond layer 136, insulating layer 138, and conductive layer 142. FIG. 2i is a cross-sectional view taken through line segment 2i-2i in FIG. 2f. FIG. 2i shows intrinsic diamond substrate 120, doped diamond layer 132, intrinsic diamond layer 136, insulating layer 138, and conductive layer 146.

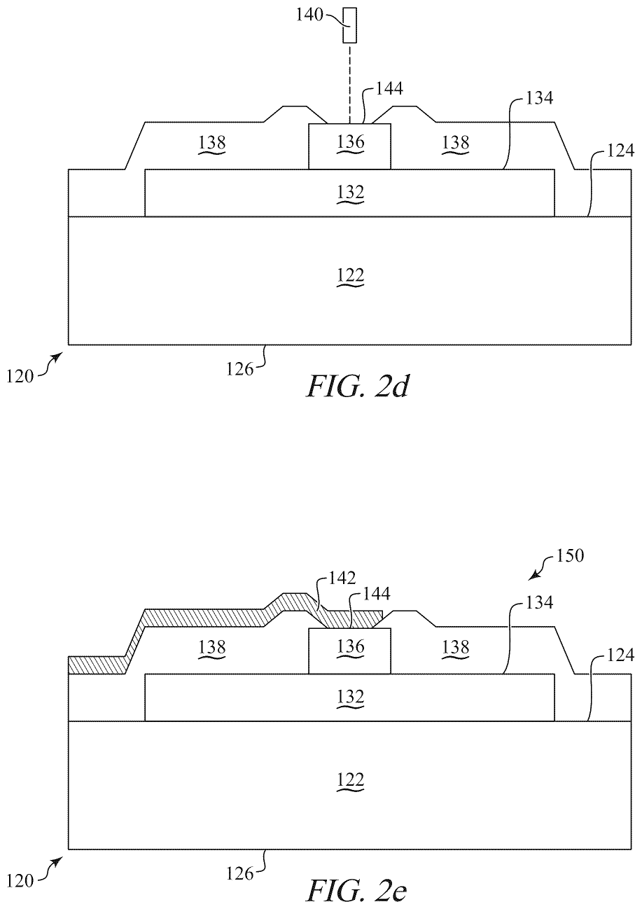

FIG. 3a illustrates further detail of the interdigitated pattern of fingers 154a and fingers 154b in diode 150. Conductive layer 142 extends from area 156 and continues over graded edge 158 to fingers 156a. Likewise, conductive layer 146 extends from area 160 and continues over graded edge 162 to fingers 156b. FIG. 3b illustrates a perspective view of the interdigitated pattern of fingers 154a extending from area 156 of conductive layer 142 over graded edge 158 and fingers 154b extending from area 160 of conductive layer 146 over graded edge 162. FIG. 3c shows further detail of area 180 from FIG. 3b with conformally applied over graded edge 170 formed in insulating layer 138, across horizontal portion 174, up graded edge 175, across horizontal portion 177, and down graded edge 178 to diamond layer 136, as further detail of graded edge 158. A cross-sectional view of conductive layer 142 conformally applied over graded edge 170, across horizontal portion 174, up graded edge 175, across horizontal portion 177, and down graded edge 178 of insulating layer 138 to diamond layer 136 can be seen in FIG. 2h. In a similar manner, a cross-sectional view of conductive layer 146 conformally applied over a similar structure like graded edge 170, across horizontal portion 174, and down graded edge 178 of insulating layer 138 to diamond layer 132, as further detail of graded edge 162, can be seen in FIG. 2i. Graded active edge 170 can be angled or vertical and operates to reduce parasitics. In one embodiment, grading can be 5.0 to 25.0 degrees, or more generally 1.0 to 90.0 degrees.

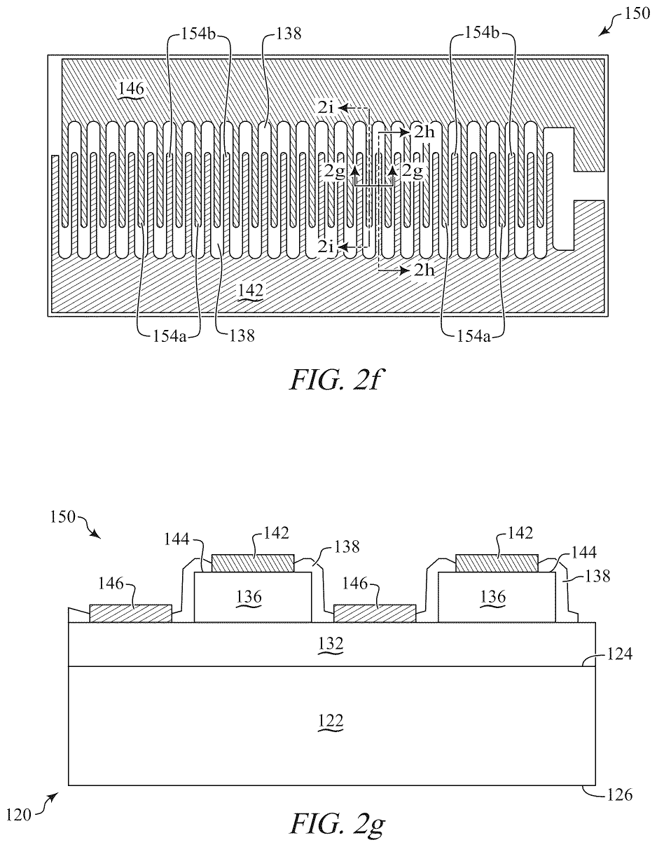

FIG. 4a is cross-sectional view of another embodiment showing an electrically conductive layer 142 formed over surface 144 of diamond layer 136 and electrically conductive layer 146 formed over surface 134 of diamond layer 132 using PVD, CVD, electrolytic plating, electroless plating process, or other suitable metal deposition process. Conductive layers 142 and 146 can be one or more layers of Al, Cu, Sn, Ni, Au, Ag, or other suitable electrically conductive material. The combination of conductive layers 142 and 164, doped diamond layer 132, and intrinsic diamond layer 136 operates as an intrinsic Schottky PI (p material 132 with intrinsic material 136 and conductive layer 142) diode 176. In this case, conductive layer 142 is the cathode and conductive layer 146 is the anode. FIG. 4b is a top view of planar diode from FIG. 4a. FIG. 4c is a top view of a non-planar diode 186.

The interdigitated structure uses a 3D graded insulator for electrode isolation, active area access, and low contribution of parasitics. FIG. 2g shows multiple digits in the active area structure. FIGS. 2h and 2i show leading metallization into the device active area and isolate metallization form conductive diamond layers. Graded edges in the insulator facilitate low resistance connections to both conductive and non-conductive active area regions.

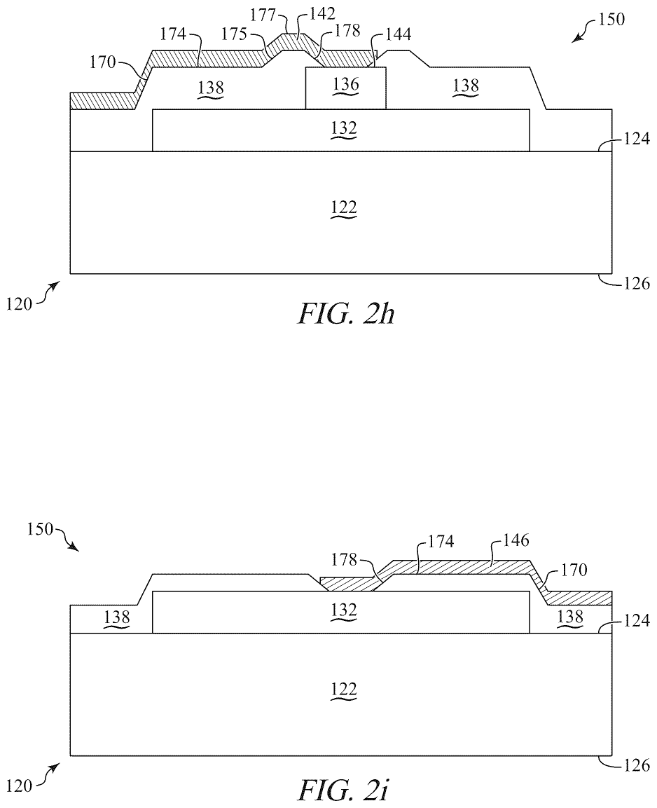

In another embodiment, substrate 120 is doped with a p-type impurity, such as boron, with a concentration similar to diamond layer 132, to form a p-type material diamond material 123, as shown in FIG. 5. Alternatively, diamond material 123 is heavily doped with a concentration greater than 10¹⁹ cm⁻³. P-type substrate 120 with p-type diamond material 123 replaces doped diamond layer 132 as the active region, hence diamond layer 132 is omitted. Intrinsic layer 136 is formed over surface 124 of substrate 120. Components having a similar function are assigned the same reference number. The p-type diamond material 123 allows for formation of electrical semiconductor devices over substrate 120, while utilizing the attributes of diamond, including hardness, thermal conductivity, wide bandgap, and useful mechanical properties. Electrically conductive layer 142 is formed over surface 124 of substrate 120 and electrically conductive layer 146 is formed over surface 134 of diamond layer 132, similar to FIG. 4a. The combination of conductive layers 142 and 146, intrinsic diamond layer 136, and doped substrate 120 operates as an intrinsic Schottky PI (p material 123 with intrinsic material 136 and conductive layer 146) diode 188. In this case, conductive layer 142 is the cathode and conductive layer 146 is the anode of diode 188. Diode 188 represents a quasi-vertical structure with current I₁₈₈ following a partial vertical and partial lateral path from anode to cathode. Diode 188 can be formed with or without an insulating layer like 138 and interdigitated fingers like 154a-154b. Diode 188 can be configured for a graded edge like 158 and 162 in FIGS. 3a-3c.

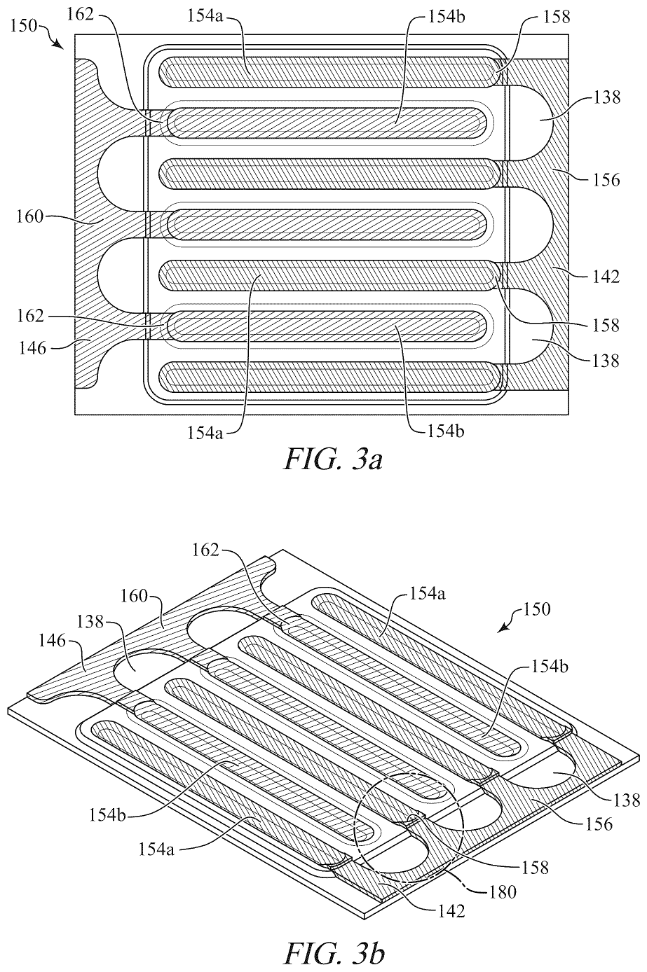

In another embodiment, substrate 120 is intrinsic material. In FIG. 6, doped diamond layer 132 is formed over surface 124 of substrate 120, similar to FIG. 2b-2c. Intrinsic diamond layer 136 is formed over surface 134 of diamond layer 132, similar to FIG. 2c. Diamond layer 190 is grown over surface 144 of diamond layer 136 using CVD, PEVCD, or HPHT, as described above. Diamond material 190 is doped with a n-type impurity, such as phosphorus, with a concentration greater than 10¹⁸ cm⁻³, to form an n-type material diamond layer. Electrically conductive layer 142 is formed over surface 192 of diamond layer 190, and electrically conductive layer 146 is formed over surface 134 of diamond layer 132. The combination of conductive layers 142 and 146, n-doped diamond layer 190, intrinsic diamond layer 136, and p-doped diamond layer 132 operates as a PIN (p material 132, intrinsic material 136, and n material 190) diode 196. In this case, conductive layer 142 is the cathode and conductive layer 146 is the anode of diode 196. Diode 196 can be formed with or without an insulating layer like 138 and interdigitated fingers like 154a-154b. Diode 196 can be configured for a graded edge like 158 and 162 in FIGS. 3a-3c. The above structure can be configured for NIP diodes in reverse order.

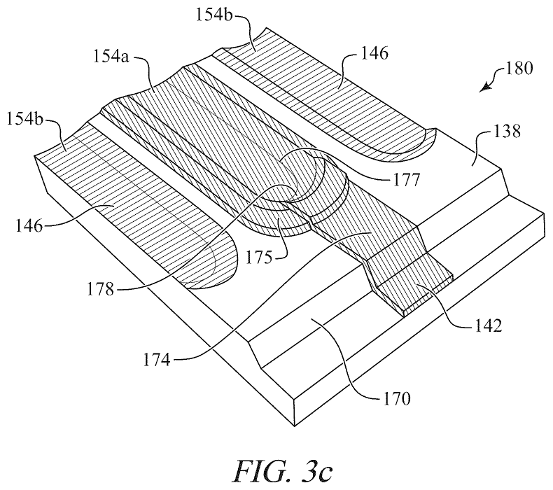

In another embodiment, substrate 120 is doped with a p-type impurity, such as boron, with a concentration similar to diamond layer 132, to form a p-type material diamond material 123, as shown in FIG. 7. Alternatively, diamond material 123 is heavily doped with a concentration greater than 10¹⁹ cm⁻³. P-type substrate 120 replaces doped diamond layer 132 as the active region, hence diamond layer 132 is omitted. Intrinsic layer 136 is formed over surface 124 of substrate 120. Diamond layer 190 is grown over diamond layer 136 using CVD, PEVCD, or HPHT, as described above. Diamond material 190 is doped with an n-type impurity, such as phosphorus. Electrically conductive layer 142 is formed over surface 192 of diamond layer 190 and electrically conductive layer 146 is formed over surface 124 of substrate 120. The combination of conductive layers 142 and 146, n-doped diamond layer 190, intrinsic diamond layer 136, and p-doped diamond layer 132 operates as a PIN (p material 123, intrinsic material 136, and n material 190) diode 198. In this case, conductive layer 142 is the cathode and conductive layer 146 is the anode of diode 198. Diode 198 can be formed with or without an insulating layer like 138 and interdigitated fingers like 154a-154b. Diode 198 can be configured for a graded edge like 158 and 162 in FIGS. 3a-3c.

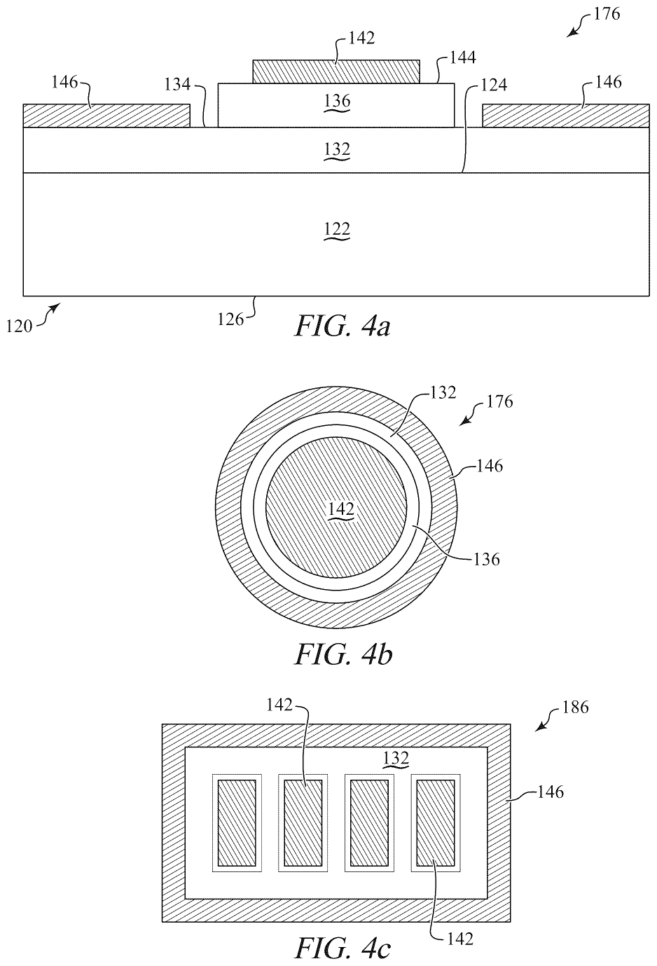

In another embodiment, similar to FIG. 2g, diode 200 includes diamond substrate 120, doped diamond layer 132, intrinsic diamond layer 136, insulating layer 138, conductive layer 142, and conductive layer 146, as shown in FIG. 8. Insulating layer 138 is formed over substrate 120, doped diamond layer 132, and intrinsic diamond layer 136. A portion of insulating layer 138 is removed by an etching process or LDA to form an opening extending to doped diamond layer 132 and intrinsic diamond layer 136. Conductive layer 142 is formed with the opening over intrinsic diamond layer 136, and conductive layer 146 is formed in the opening over doped diamond layer 132. Edge 202 shows grading of insulating layer 138. Edge 204 is an active area region grading, and edge 206 shows drift layer grading.

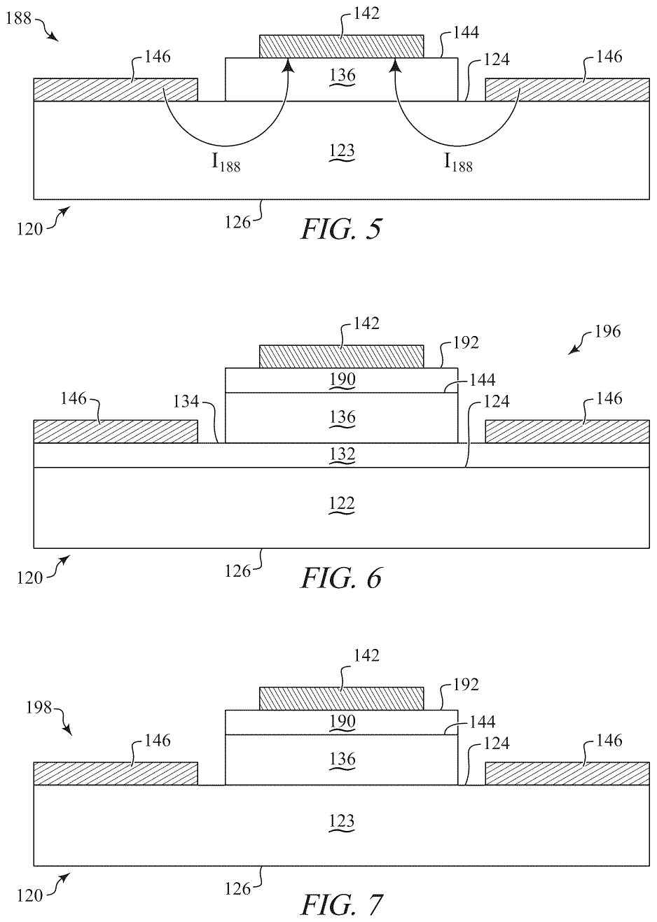

In another embodiment, substrate 120 is doped with a p-type impurity, such as boron, with a concentration similar to diamond layer 132, to form a p-type material diamond material 123, as shown in FIG. 9. Alternatively, diamond material 123 is heavily doped with a concentration greater than 10¹⁸ cm⁻³. P-type substrate 120 replaces doped diamond layer 132 as the active region, hence diamond layer 132 is omitted. Intrinsic layer 136 is formed over surface 124 of substrate 120. Electrically conductive layer 142 is formed over surface 144 of diamond layer 136 and electrically conductive layer 146 is formed over surface 126 of substrate 120. The combination of conductive layers 142 and 146, intrinsic diamond layer 136, and doped substrate 120 operates as an intrinsic Schottky PI (p material 123 with intrinsic material 136 and conductive layer 146) diode 210. In this case, conductive layer 142 is the cathode and conductive layer 146 is the anode of diode 210. Diode 210 represents a vertical structure with current I₂₁₀ following a vertical path from anode to cathode. Diode 210 can be formed with or without an insulating layer like 138 and interdigitated fingers like 154a-154b. Diode 210 can be configured for a graded edge like 158 and 162 in FIGS. 3a-3c.

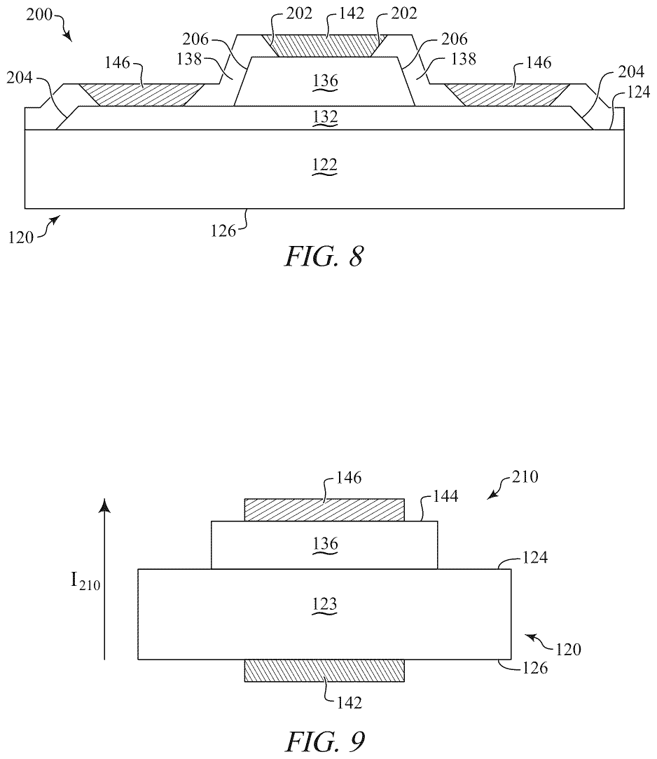

In another embodiment, similar to FIGS. 6, 7, and 9, diamond layer 214 is grown over diamond layer 136 using CVD, PEVCD, or HPHT, as shown in FIG. 10. Diamond material 214 is doped with an n-type impurity, such as phosphorus. Electrically conductive layer 142 is formed over surface 216 of diamond layer 214 and electrically conductive layer 146 is formed over surface 124 of substrate 120. The combination of conductive layers 142 and 146, n-doped diamond layer 214, intrinsic diamond layer 136, and p-doped diamond layer 132 operates as a PIN (p material 123, intrinsic material 136, and n material 214) diode 218. In this case, conductive layer 142 is the cathode and conductive layer 146 is the anode of diode 218. Diode 218 can be formed with or without an insulating layer like 138 and interdigitated fingers like 154a-154b. Diode 218 can be configured for a graded edge like 158 and 162 in FIGS. 3a-3c.

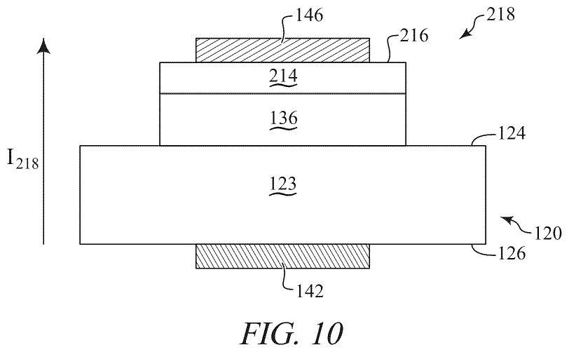

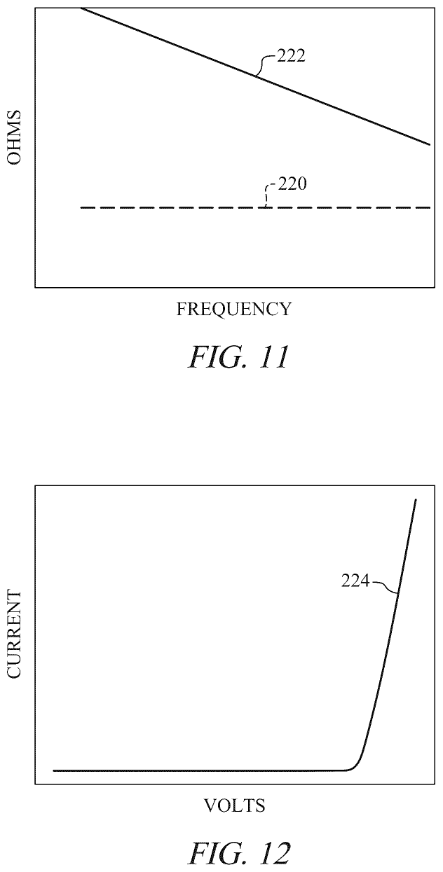

FIG. 11 is a graph of Z11 Magnitude in ohms versus frequency for diodes 150, 176, 186, 188, 196, 198, 200, and 210. Trace 220 represents the OFF-state impedance characteristic and trace 22 represents the ON-state characteristic. De-embedded results where the true active area performance is calculated have yielded a frequency figure of merit values as high as 100 GHz, with the potential for 1.0 THz and more. Trace 224 in FIG. 12 is a graph of current versus voltage for diodes 150, 176, 186, 188, 196, 198, 200, and 210. The data shows a low turn on forward, current densities greater than 200 kA/cm², and high power operation.

In summary, diamond based solid state high frequency and/or power device structured mitigate current crowding effects and parasitic resistances in semiconducting diamond layers, reduce on-resistance, and overall parasitics. The 3D structure of the insulator layer allows for more effective access to device active areas and minimizes parasitic resistances and capacitance. Such structures are optimized for diamond due to the unique properties of diamond for handling high power and high frequency applications where other materials might fail. The high thermal conductivity enables high power dissipation away from the device active areas, allowing for higher operating powers and lifetime, as compared to state-of-the-art devices. Additionally, other high power materials suffer the possibility of thermal runaway, whereas diamond's performance improves and is stable at high temperatures and for high temperature applications.

Low thermal noise, low leakage, and low on-resistance of diamond make it ideal for RF applications where low Coff and low Ron are needed for high frequencies in both the GHz and THz range.

The diode structure can be planar or interdigitated depending on which properties must be leveraged depending on the application. Interdigitated devices cater greatly towards high frequency applications. Planar devices suffer from current crowding when the smallest linear dimension of the contact is less than the transfer length of the structure. Contact widths exceeding the transfer length, support current at the edge of the device, greatly reducing the effective active area while the parasitics of the total area remain. Therefore, the parasitic capacitance per unit area is greatly increased since a large portion of the device contributes only to the parasitics and not the overall device performance. Interdigitated structures are one way to break the area into smaller segments which are well within the transfer length limit.

Another way of dealing with current crowding is increasing the doping and or the thickness of the boron doped diamond, hence increasing the transfer length. This option is more suitable for high voltage and high power applications.

In the present invention, insulating layer 138 is graded to allow for a smooth break free transition up the insulator. Grading is shallow ranging from 5.0 to 25.0 degrees (can be adjusted) and doubles as a field plate for the device structure. The diamond edges are also graded to allow for a smooth transition of metal on the oxide to come over these edges without breaks or concerns for electromigration or burnout. Grading can also be controlled from 1.0 to 90.0 degrees. There is a balance between grading and parasitic capacitance that should be accounted for and balance with the parasitic resistance due to not introducing a gradient. The grading in the insulator provides an interconnect ready structure that allows for the fabrication of multi-level interconnects and more complex connection schemes between devices. Interconnects would be useful if multiple planar devices needed to be connected in parallel or series for achieving target current or power specs.

While one or more embodiments of the present invention have been illustrated in detail, the skilled artisan will appreciate that modifications and adaptations to those embodiments may be made without departing from the scope of the present invention as set forth in the following claims.

What is claimed:

1. A semiconductor device, comprising:
a substrate;
a first diamond layer formed over a surface of the substrate; and
an insulating layer formed over the first diamond layer, the insulating layer including a first graded edge.

2. The semiconductor device of claim 1, further including a second diamond layer formed over the first diamond layer, wherein the insulating layer further extends over the second diamond layer.

3. The semiconductor device of claim 2, wherein the first diamond layer includes a dopant material and the second diamond layer includes an intrinsic material.

4. The semiconductor device of claim 2, further including:
a first conductive layer formed over the insulating layer and contacting the first diamond layer; and
a second conductive layer formed over the insulating layer and contacting the second diamond layer.

5. The semiconductor device of claim 4, wherein the first conductive layer and second conductive layer are interdigitated.

6. The semiconductor device of claim 1, wherein the insulating layer includes a second graded edge.

7. A semiconductor device, comprising:
a substrate including a diamond material; and
a first diamond layer formed over a surface of the substrate to function as a diode.

8. The semiconductor device of claim 7, further including an insulating layer formed over the first diamond layer, the insulating layer including a graded edge.

9. The semiconductor device of claim 7, further including a second diamond layer formed over the first diamond layer.

10. The semiconductor device of claim 9, further including a third diamond layer formed over the second diamond layer.

11. The semiconductor device of claim 9, wherein the first diamond layer includes a dopant material and the second diamond layer includes an intrinsic material.

12. The semiconductor device of claim 9, further including:
a first conductive layer formed over the insulating layer and contacting the first diamond layer; and
a second conductive layer formed over the insulating layer and contacting the second diamond layer.

13. The semiconductor device of claim 12, wherein the first conductive layer and second conductive layer are interdigitated.

14. A method of making a semiconductor device, comprising:
providing a substrate including a diamond material;
a first diamond layer formed over a surface of the substrate to function as a diode; and
forming an insulating layer over the first diamond layer, the insulating layer including a first graded edge.

15. The method of claim 14, further including forming a second diamond layer over the first diamond layer, wherein the insulating layer further extends over the second diamond layer.

16. The method of claim 15, further including forming a third diamond layer over the second diamond layer.

17. The method of claim 15, wherein the first diamond layer includes a dopant material and the second diamond layer includes an intrinsic material.

18. The method of claim 15, further including:
forming a first conductive layer over the insulating layer and contacting the first diamond layer; and
forming a second conductive layer over the insulating layer and contacting the second diamond layer.

19. The method of claim 18, wherein the first conductive layer and second conductive layer are interdigitated.

20. The method of claim 14, wherein the insulating layer includes a second graded edge.
